(19) United States
(12) Patent Application Publication
(10) Pub. No.: US 2025/0242417 A1
(43) Pub. Date: Jul. 31, 2025

(54) COATED TOOL AND CUTTING TOOL

(71) Applicant: KYOCERA Corporation, Kyoto-shi (JP)

(72) Inventor: Hiroki ARITA, Satsumasendai-shi (JP)

(21) Appl. No.: 19/064,555

(22) Filed: Feb. 26, 2025

Related U.S. Application Data
(63) Continuation-in-part of application No. PCT/JP2023/031997, filed on Aug. 31, 2023.

(30) Foreign Application Priority Data
Aug. 31, 2022 (JP) 2022-138802

(51) Int. Cl. B23B 27/14

(52) U.S. Cl. CPC B23B 27/148; B23B 2228/105

(57) ABSTRACT

A coated tool includes a base and a coating layer. The coating layer includes a plurality of crystal grains. The plurality of crystal grains include a plurality of regions having crystallographic orientations different from each other. A value of D2/D1 is 0.55 to 0.95, where the crystallographic orientations of the plurality of crystal grains in the coating layer are analyzed from a planar direction of the coating layer by using a TEM electron-diffraction mapping method, a first crystal grain map and a second crystal grain map are created, D1 is an average grain size of the crystal grain evaluated by taking a weighted average based on an area ratio from the first crystal grain map, and D2 is an average grain size of the crystal grain evaluated by taking a weighted average based on an area ratio from the second crystal grain map.

### CROSS-REFERENCE TO RELATED APPLICATION(S)

This application is a continuation-in-part of International Application No. PCT/JP2023/031997, filed on Aug. 31, 2023, the entire contents of which are herein incorporated by reference, and which is based upon and claims the benefit of priority to Japanese Patent Application No. 2022-138802, filed on Aug. 31, 2022, the entire contents of which are herein incorporated by reference.

### FIELD

The present disclosure relates to a coated tool and a cutting tool.

### BACKGROUND

Known tools to be used for cutting processing such as turning processing or milling processing include a coated tool in which a surface of a base made of cemented carbide alloy, cermet, ceramic, or the like is coated with a coating layer to improve wear resistance and the like.

### SUMMARY

A coated tool according to an aspect of the present disclosure includes a base and a coating layer located on the base. The coating layer includes a plurality of crystal grains. The plurality of crystal grains include a crystal grain including a plurality of regions having crystallographic orientations different from each other. Average grain sizes D1 and D2 of the crystal grains in the coating layer defined by the following method have the following relationship: D2/D1=0.55 to 0.95.

### Definition of D1 and D2

Crystallographic orientations of the plurality of crystal grains in the coating layer are analyzed from a planar direction of the coating layer by using a TEM electron-diffraction mapping method. D1 is an average grain size of a crystal grain evaluated by taking a weighted average based on an area ratio from a first crystal grain map created by using, as a crystal grain boundary, a region obtained by excluding a Σ3CSL (coincidence grain boundary) from a region in which an orientation difference between adjacent measurement points is 5° or more. D2 is an average grain size of the crystal grain evaluated by taking a weighted average based on an area ratio from a second crystal grain map created by using, as a crystal grain boundary, a region in which an orientation difference between adjacent measurement points is 5° or more and the Σ3CSL (coincidence grain boundary).

### BRIEF DESCRIPTION OF DRAWING(S)

FIG. 1 is a perspective view illustrating an example of a coated tool according to an embodiment.

FIG. 2 is a side sectional view illustrating an example of the coated tool according to the embodiment.

FIG. 3 is a schematic view illustrating an example of a coating layer according to the embodiment.

FIG. 4 is a cross-sectional view illustrating an example of a coating layer according to a first embodiment.

FIG. 5A is a schematic view describing a Ti/Al ratio in a coating layer according to the first embodiment.

FIG. 5B is a schematic view describing a Cr/Al ratio in the coating layer according to the first embodiment.

FIG. 6A is a cross-sectional view illustrating an example of a first coating layer included in the coating layer according to the first embodiment.

FIG. 6B is a cross-sectional view illustrating an example of a second coating layer included in the coating layer according to the first embodiment.

FIG. 6C is a cross-sectional view illustrating an example of a third coating layer included in the coating layer according to the first embodiment.

FIG. 7 is a cross-sectional view illustrating an example of a coating layer according to a second embodiment.

FIG. 8A is a schematic view describing a Ti/Al ratio in the coating layer according to the second embodiment.

FIG. 8B is a schematic view describing a Cr/Al ratio in the coating layer according to the second embodiment.

FIG. 9 is a cross-sectional view illustrating an example of a fourth coating layer included in the coating layer according to the second embodiment.

FIG. 10 is a diagram schematically illustrating an example of a deposition apparatus for forming a coating layer on a base.

FIG. 11 is a front view illustrating an example of a cutting tool according to the embodiment.

### DESCRIPTION OF EMBODIMENT(S)

The following is a detailed description of embodiments of a coated tool and a cutting tool according to the present disclosure (hereinafter referred to as “embodiments”) with reference to the drawings. The coated tool and the cutting tool according to the present disclosure are not limited by the embodiments. Embodiments can be appropriately combined so as not to contradict each other in terms of processing content. In the following embodiments, the same portions are denoted by the same reference signs, and redundant explanations are omitted.

In the embodiments described below, expressions such as “constant”, “orthogonal”, “perpendicular”, or “parallel” may be used, but these expressions do not need to be strictly “constant”, “orthogonal”, “perpendicular”, or “parallel”. In other words, each of the expressions described above allows deviations in, for example, manufacturing accuracy, installation accuracy, or the like.

Known tools to be used for cutting processing such as turning processing or milling processing include a coated tool in which a surface of a base made of cemented carbide alloy, cermet, ceramic, or the like is coated with a coating layer to improve wear resistance and the like.

The related art described above has room for further improvement in terms of extending tool life.

Therefore, it is expected that a technique that can overcome the aforementioned problem and extend the tool life will be achieved.

### Coated Tool

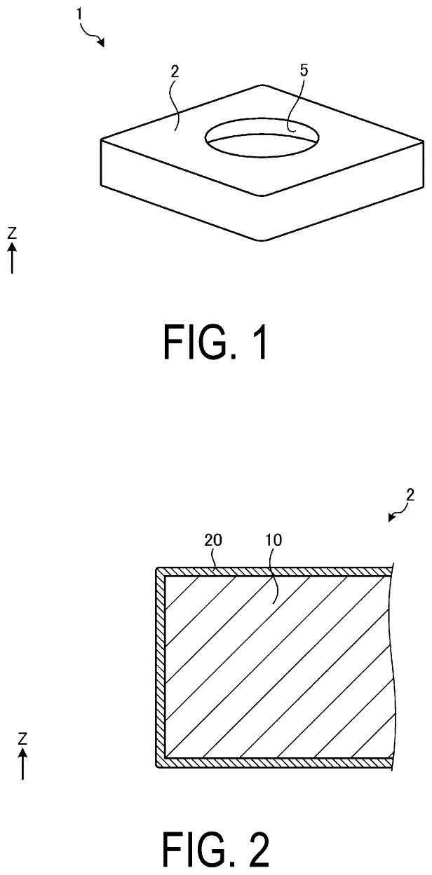

FIG. 1 is a perspective view illustrating an example of a coated tool according to an embodiment. FIG. 2 is a side sectional view illustrating an example of the coated tool according to the embodiment. As illustrated in FIG. 1, the coated tool 1 according to the embodiment includes a tip body 2.

### Tip Body 2

The tip body 2 includes a hexagonal shape in which a shape of an upper surface and a lower surface (surfaces intersecting a Z-axis illustrated in FIG. 1) is a parallelogram.

One corner portion of the tip body 2 functions as a cutting edge portion. The cutting edge portion has a first surface (for example, an upper surface) and a second surface (for example, a side surface) connected to the first surface. In the embodiment, the first surface functions as a “rake face” for scooping chips generated by cutting, and the second surface functions as a “flank face”. A cutting edge is located on at least a part of a ridge line where the first surface and the second surface intersect with each other, and the coated tool 1 cuts a workpiece through application of the cutting edge to the workpiece.

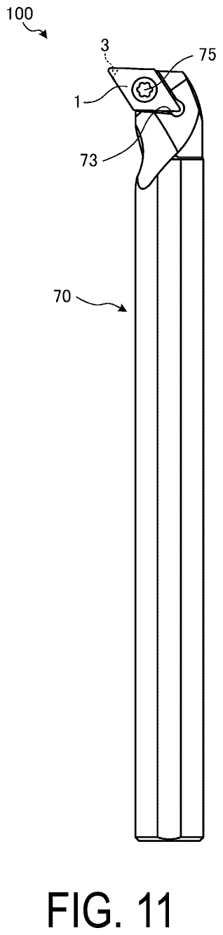

A through hole 5 vertically penetrating the tip body 2 is located in the center portion of the tip body 2. A screw 75 for attaching the coated tool 1 to a holder 70 to be described below is inserted into the through hole 5 (see FIG. 11).

As illustrated in FIG. 2, the tip body 2 has a base 10 and a coating layer 20.

### Base 10

The base 10 is made of, for example, cemented carbide alloy. The cemented carbide alloy contains tungsten (W), specifically, tungsten carbide (WC). The cemented carbide alloy may contain nickel (Ni) or cobalt (Co). Specifically, the base 10 is made of WC-based cemented carbide alloy containing WC grains as a hard phase component and Co as a main component of a binder phase.

The base 10 may be made of cermet. The cermet contains, for example, titanium (Ti), specifically, titanium carbide (TiC) or titanium nitride (TiN). The cermet may contain Ni or Co.

The base 10 may be made of a cubic boron nitride sintered body containing cubic boron nitride (cBN) particles. The base 10 may contain not only the cubic boron nitride (cBN) particles, but also particles of, for example, hexagonal boron nitride (hBN), rhombohedral boron nitride (rBN), or wurtzite boron nitride (wBN).

The base 10 may be made of ceramic. An example of the ceramic includes Al₂O₃ (aluminum oxide). Examples of the type of Al₂O₃ include κ-Al₂O₃ and α-Al₂O₃. The ceramic may contain other elements in the aluminum oxide. For example, the ceramic may contain, in addition to the aluminum oxide, at least one selected from the group consisting of magnesium (Mg), calcium (Ca), strontium (Sr), silicon (Si), and group 3 elements in the periodic table.

### Coating Layer 20

The base 10 is coated with the coating layer 20 for the purpose of, for example, increasing the wear resistance and heat resistance of the base 10. In the example in FIG. 2, the coating layer 20 entirely coats the base 10. The coating layer 20 may be located at least on the base 10. When the coating layer 20 is located on the first surface (here, the upper surface) of the base 10, the first surface has high wear resistance and heat resistance. When the coating layer 20 is located on the second surface (here, the side surface) of the base 10, the second surface has high wear resistance and heat resistance.

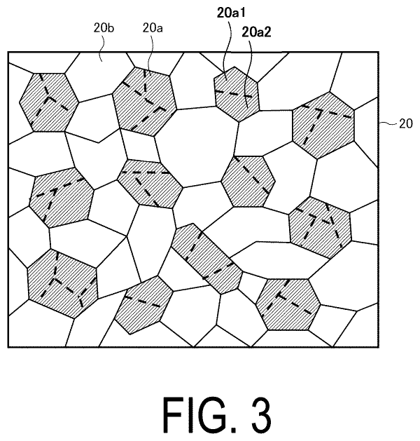

Here, a specific configuration of the coating layer 20 will be described with reference to FIG. 3. FIG. 3 is a schematic view illustrating an example of a coating layer according to the embodiment. The coating layer 20B according to the embodiment includes a plurality of crystal grains. For example, as illustrated in FIG. 3, the coating layer 20 includes a plurality of crystal grains 20a and 20b inside the coating layer 20. The inside of the coating layer 20 illustrated in FIG. 3 is a plane parallel to the surface of the base 10 provided thereon with the coating layer 20.

For example, the plurality of crystal grains 20a and 20b in the coating layer 20 can be identified by analysis using a TEM electron-diffraction mapping method (TEM ED-Map). More specifically, first, the TEM electron-diffraction mapping method is used to measure an electron-diffraction pattern at each measurement point while scanning the inside of the coating layer 20 with an electron beam probe to obtain the crystallographic orientation corresponding to each measurement point in the crystal grain map of the coating layer 20. When the difference in crystallographic orientation between adjacent measurement points in the crystal grain map of the coating layer 20 is, for example, 5° or more, a boundary line is drawn between the adjacent measurement points. A region surrounded by the boundary line in the crystal grain map of the coating layer 20 can be identified as a crystal grain. In the identification, the crystal grains can be identified by division into a case where a region obtained by excluding the Σ3CSL (coincidence grain boundary) from the region in which the orientation difference between the adjacent measurement points is 5° or more is set as the crystal grain boundary, and a case where the region in which the orientation difference between the adjacent measurement points is 5° or more and the Σ3CSL (coincidence grain boundary) are set as the crystal grain boundary.

In the coating layer 20, as illustrated in FIG. 3, the plurality of crystal grains 20a and 20b include a (single) crystal grain 20a (first crystal grain 20a) having a plurality of regions 20a1, 20a2 having crystallographic orientations different from each other in the coating layer 20. The plurality of crystal grains 20a and 20b include a (single) crystal grain 20b (second crystal grain 20b) having a substantially constant crystallographic orientation in the coating layer 20. All of the plurality of crystal grains may be the crystal grain 20a having a plurality of regions 20a1, 20a2 having crystallographic orientations different from each other. The crystal grain 20a including a plurality of regions 20a1, 20a2 having crystallographic orientations different from each other may be a single crystal grain 20a having a region with a continuously varying crystallographic orientation. In the example illustrated in FIG. 3, the plurality of crystal grains include a plurality of first crystal grains 20a and a plurality of second crystal grains 20b.

D1 is an average grain size of a crystal grain evaluated by taking a weighted average based on an area ratio from a first crystal grain map created by using, as a crystal grain boundary, a region obtained by excluding a Σ3CSL (coincidence grain boundary) from a region in which an orientation difference between adjacent measurement points is 5° or more. D2 is an average grain size of a crystal grain evaluated by taking a weighted average based on an area ratio from a second crystal grain map created by using, as a crystal grain boundary, a region in which an orientation difference between adjacent measurement points is 5° or more and the Σ3CSL (coincidence grain boundary). In this case, a value of D2/D1 may be 0.55 to 0.95.

For example, analysis using the TEM electron-diffraction mapping method can identify between a single crystal grain 20a having a plurality of regions 20a1, 20a2 having crystallographic orientations different from each other and/or a single crystal grain 20a having a region with a continuously varying crystallographic orientation. To be more specific, by using the TEM electron-diffraction mapping method, a single crystal grain having a plurality of regions with colors different from each other in an inverse pole figure orientation map inside the coating layer 20 can be identified as the single crystal grain 20a having a plurality of regions 20a1, 20a2 having crystallographic orientations different from each other. Similarly, by using the TEM electron-diffraction mapping method, a single crystal grain having a region with a continuously varying color in the inverse pole figure orientation map inside the coating layer 20 can be identified as the single crystal grain 20a having a region with a continuously varying crystallographic orientation.

By analysis using the TEM electron-diffraction mapping method, an orientation difference of 5° or more is analyzed as a crystal grain boundary. Crystal grain maps are created by division into a case where the Σ3CSL (coincidence grain boundary) is not a crystal grain boundary and a case where the Σ3CSL (coincidence grain boundary) is a crystal grain boundary. Next, on each crystal grain map, the average grain sizes D1 and D2 can be calculated by taking a weighted average based on an area ratio to evaluate a ratio of D2/D1. The crystal grain map data and the crystallographic orientation analysis system can be used to output an average KAM (local orientation difference) value for each crystal grain. At this time, the adjacent pixel having an orientation difference of 5° or more with respect to a pixel at a measurement center is regarded as a pixel exceeding the grain boundary from the single crystal in which the pixel at the measurement center is located such that the pixel is excluded from a target for the calculation for the KAM value.

If the plurality of crystal grains 20a and 20b include a single crystal grain 20a having a plurality of regions 20a1, 20a2 having crystallographic orientations different from each other in the coating layer 20, the development of cracks in the single crystal grain 20a having a plurality of regions 20a1, 20a2 having crystallographic orientations different from each other can be reduced. In particular, when the value of D2/D1 is less than 0.95, the ratio of the coincidence grain boundaries in the crystal increases, the development of cracks within the coating layer 20 is easily suppressed, and thus, the strength of the coating layer is improved. When the value of D2/D1 is more than 0.55, the variation in orientation in the crystal does not become excessively large, plastic deformation of the coating layer 20 is suppressed, and favorable wear resistance is exhibited. Deterioration of chipping resistance is suppressed, and the longevity of the tool is improved. As a result, the longevity of the coated tool 1 can be extended.

In the coating layer 20 included in the plurality of crystal grains 20a and 20b, when the average KAM (local orientation difference) value of each of the crystal grains is evaluated by using the crystal grain map data and the crystallographic orientation analysis system, a ratio of crystal grains having the average KAM value of 1 or more may be 50% or more and 80% or less. In such a case, the development of cracks in a single crystal grain 20a having a plurality of regions 20a1, 20a2 having crystallographic orientations different from each other can be further reduced. Therefore, the coating layer 20B can have further improved fracture resistance. This further extends the longevity of the coated tool 1.

The plurality of crystal grains 20a, 20b may include a composite nitride. In such a case, the coating layer 20 including a single crystal grain 20a having a plurality of regions 20a1, 20a2 having crystallographic orientations different from each other can be obtained more successfully. Therefore, the coating layer 20B can have improved fracture resistance more easily. As a result, the longevity of the coated tool 1 can be further extended.

As in the example illustrated in FIG. 3, the plurality of first crystal grains 20a may be located away from each other. In such a case, even when a crack develops in one of the plurality of first crystal grains 20a, the crack is unlikely to propagate to another first crystal grain 20a. Therefore, it is easy to avoid the crack from spreading over a wide range of the coating layer 20. As a result, the longevity of the coated tool 1 can be extended.

At this time, as in the example illustrated in FIG. 3, a plurality of second crystal grains 20a may be located between the plurality of first crystal grains 20b. In such a case, even when a crack develops in one of the plurality of first crystal grains 20a, it is easy to avoid further development of the crack by the second crystal grain 20b. Therefore, it is easy to avoid the crack from spreading over a wide range of the coating layer 20. As a result, the longevity of the coated tool 1 can be extended.

As in the example illustrated in FIG. 3, at least two of the plurality of second crystal grains 20b may be adjacent to each other. In such a case, it is easy to avoid the above-described crack from developing due to the plurality of second crystal grains 20b while homogenizing the coating layer 20 by making the second crystal grains 20b fine. Therefore, it is easy to avoid the crack from spreading over a wide range of the coating layer 20. As a result, the longevity of the coated tool 1 can be extended.

Here, a more specific configuration of the coating layer 20 will be described in which the crystal grains 20a having a plurality of regions 20a1, 20a2 having crystallographic orientations different from each other are provided, the value of D2/D1 is 0.55 to 0.95, and the ratio of crystal grains having the average KAM value of 1 or more is 50% or more and 80% or less. That is, the configuration of the coating layer 20A according to the first embodiment and the configuration of the coating layer 20B according to the second embodiment for realizing the coating layer 20 including the crystal grain 20a having a plurality of regions 20a1, 20a2 having crystallographic orientations different from each other, will be described.

### Coating Layer 20A According to First Embodiment

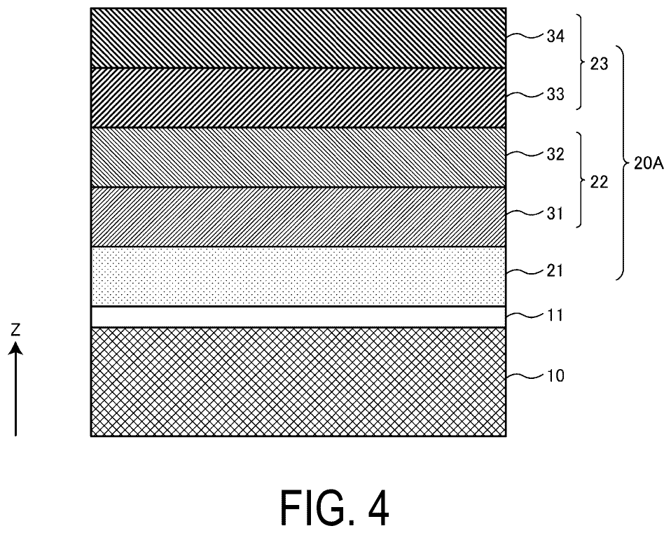

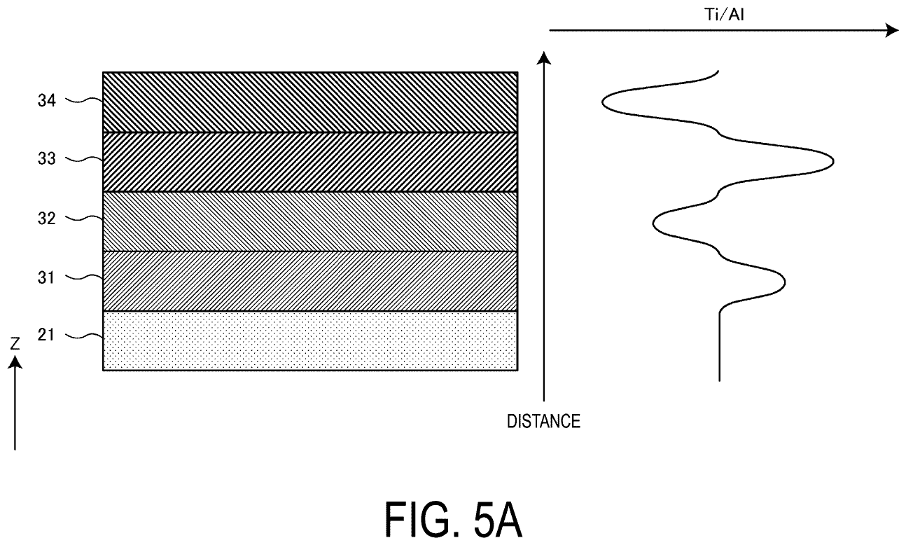

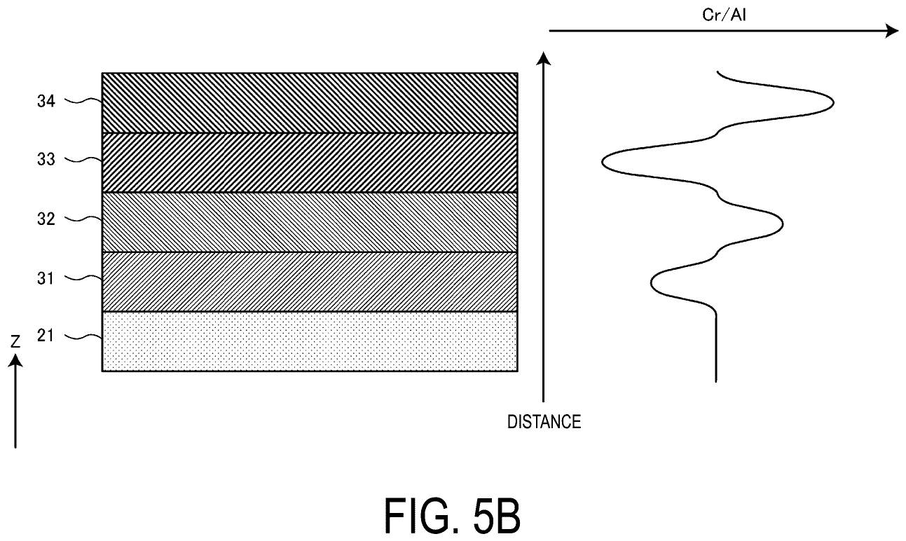

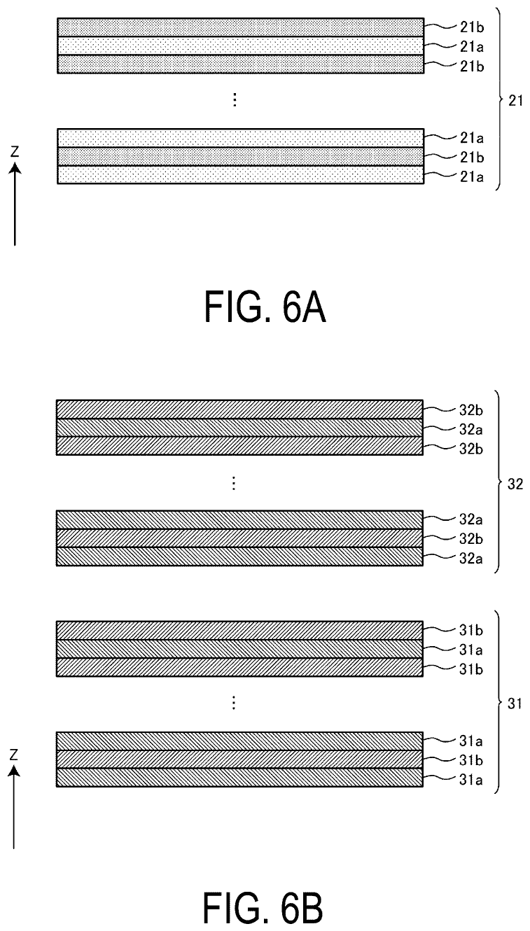

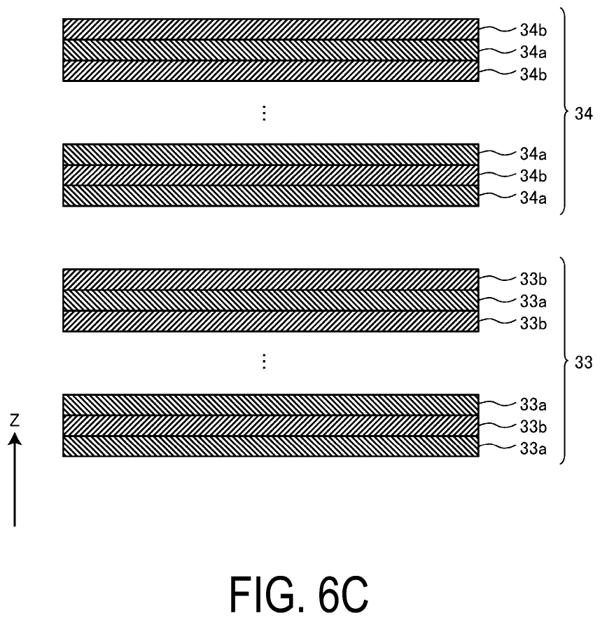

Here, a specific configuration of the coating layer 20A according to a first embodiment will be described with reference to FIGS. 4, 5A, 5B, 6A, 6B, and 6C. FIG. 4 is a cross-sectional view illustrating an example of a coating layer according to the first embodiment. FIG. 5A is a schematic view describing a Ti/Al ratio in the coating layer according to the first embodiment. FIG. 5B is a schematic view describing a Cr/Al ratio in the coating layer according to the first embodiment. FIG. 6A is a cross-sectional view illustrating an example of a first coating layer included in the coating layer according to the first embodiment. FIG. 6B is a cross-sectional view illustrating an example of a second coating layer included in the coating layer according to the first embodiment. FIG. 6C is a cross-sectional view illustrating an example of a third coating layer included in the coating layer according to the first embodiment.

As illustrated in FIG. 4, the coating layer 20A according to the first embodiment serving as the coating layer 20 includes a first coating layer 21 located on the base 10, a second coating layer 22 located on the first coating layer 21, and a third coating layer 23 located on the second coating layer 22. When the tip body 2 includes the intermediate layer 11 in addition to the base 10 and the coating layer 20A serving as the coating layer 20, the intermediate layer 11 is located between the base 10 and the first coating layer 21 as illustrated in FIG. 4. In such a case, the first coating layer 21 is located on the base 10 via the intermediate layer 11.

### First Coating Layer 21

The first coating layer 21 contains Al, Ti, Cr, and N. The first coating layer 21 may be an AlTiCrN layer containing AlTiCrN, which is a nitride of Al, Ti, and Cr. Note that the expression “AlTiCrN” means that Al, Ti, Cr, and N are present at any ratio, and does not necessarily mean that Al, Ti, Cr, and N are present at a ratio of 1:1:1:1. The first coating layer 21 has a thickness of, for example, 500 nm or more and 1500 nm or less.

The first coating layer 21 located on the base 10 is capable of reducing residual stresses between the base 10 and the coating layers (the second coating layer 22 and the third coating layer 23 in the coating layer 20A) located on the first coating layer 21. That is, the first coating layer 21 is capable of reducing the residual stresses between the base 10 and the coating layer 20A. Thus, separation or cracking between the base 10 and the coating layer 20A can be reduced. In other words, the adhesion between the base 10 and the coating layer 20A can be improved. As a result, the longevity of the coated tool 1 can be extended.

### Second Coating Layer 22

As illustrated in FIG. 4, the second coating layer 22 includes a first film 31 and a second film 32. Each of the first film 31 and the second film 32 contains Al, Ti, Cr, and N. Each of the first film 31 and the second film 32 may be an AlTiCrN film containing AlTiCrN, which is a nitride of Al, Ti, and Cr. A thickness of the first film 31 is, for example, 200 nm or more and 400 nm or less. A thickness of the second film 32 is, for example, 200 nm or more and 400 nm or less.

The first film 31 has a Ti/Al ratio higher than a Ti/Al ratio in the first coating layer 21. Here, the Ti/Al ratio means a ratio of the number of Ti atoms to the number of Al atoms. This improves the wear resistance and the chipping resistance of the coating layer 20A without significantly increasing the residual stresses between the base 10 and the coating layer (the third coating layer 23 in the coating layer 20A) located on the second coating layer 22. The first film 31 may have a Cr/Al ratio lower than a Cr/Al ratio in the first coating layer 21.

The second film 32 has a Cr/Al ratio higher than a Cr/Al ratio in the first coating layer 21. Here, the Cr/Al ratio means a ratio of the number of Cr atoms to the number of Al atoms. This improves the lubricity and the anti-adhesion properties of the coating layer 20A without significantly increasing the residual stresses between the base 10 and the coating layer (the third coating layer 23 in the coating layer 20A) located on the second coating layer 22. The second film 32 may have a Ti/Al ratio lower than a Ti/Al ratio in the first coating layer 21.

The second coating layer 22 can improve the wear resistance and the chipping resistance of the coating layer 20A and also improve the lubricity and the anti-adhesion properties of the coating layer 20A without significantly increasing the residual stresses between the base 10 and the coating layer located on the second coating layer 22. As a result, the longevity of the coated tool 1 can be extended.

### Third Coating Layer 23

As illustrated in FIG. 4, the third coating layer 23 includes a third film 33 and a fourth film 34. Each of the third film 33 and the fourth film 34 contains Al, Ti, Cr, and N. Each of the third film 33 and the fourth film 34 may be an AlTiCrN film containing AlTiCrN, which is a nitride of, for example, Al, Ti, and Cr. A thickness of the third film 33 is, for example, 200 nm or more and 400 nm or less. A thickness of the fourth film 34 is, for example, 200 nm or more and 400 nm or less.

The third film 33 has a Ti/Al ratio higher than a Ti/Al ratio in the first film 31. Here, the Ti/Al ratio means a ratio of the number of Ti atoms to the number of Al atoms. This can improve the wear resistance and the chipping resistance of the coating layer 20A. The third film 33 may have a Cr/Al ratio lower than a Cr/Al ratio in the first film 31.

The fourth film 34 has a Cr/Al ratio higher than a Cr/Al ratio in the second film 32. Here, the Cr/Al ratio means a ratio of the number of Cr atoms to the number of Al atoms. This can improve the lubricity and the anti-adhesion properties of the coating layer 20A. The fourth film 34 may have a Ti/Al ratio lower than a Ti/Al ratio in the second film 32.

The third coating layer 23 can improve the wear resistance and the chipping resistance of the coating layer 20A and also improve the lubricity and the anti-adhesion properties of the coating layer 20A. As a result, the longevity of the coated tool 1 can be extended.

### Example of Ti/Al Ratio in Coating Layer 20A

As illustrated in FIG. 5A, the Ti/Al ratio in the coating layer 20A may continuously change in the thickness-wise direction of the coating layer 20A. When the Ti/Al ratio in the target region of the coating layer 20A is not constant, the mean value of the Ti/Al ratios in such a region may be used as the Ti/Al ratio in the region.

In the example illustrated in FIG. 5A, the Ti/Al ratio in the coating layer 20A is substantially constant in the first coating layer 21. The Ti/Al ratio in the coating layer 20A is locally maximum in the first film 31 included in the second coating layer 22 and the third film 33 included in the third coating layer 23. The Ti/Al ratio in the coating layer 20A is locally minimum in the second film 32 included in the second coating layer 22 and the fourth film 34 included in the third coating layer 23.

Here, not only the Ti/Al ratio in the first film 31 may be larger than the Ti/Al ratio in the first coating layer 21, but also a local maximum value of the Ti/Al ratio in the first film 31 may be larger than the Ti/Al ratio in the first coating layer 21. Not only the Ti/Al ratio in the third film 33 may be larger than the Ti/Al ratio in the first film 31, but also the local maximum value of the Ti/Al ratio in the third film 33 may be larger than the local maximum value of the Ti/Al ratio in the first film 31.

Not only the Ti/Al ratio in the second film 32 may be smaller than the Ti/Al ratio in the first coating layer 21, but also the local minimum value of the Ti/Al ratio in the second film 32 may be smaller than the Ti/Al ratio in the first coating layer 21. Not only the Ti/Al ratio in the fourth film 34 may be smaller than the Ti/Al ratio in the second film 32, but also the local minimum value of the Ti/Al ratio in the fourth film 34 may be smaller than the local minimum value of the Ti/Al ratio in the second film 32.

### Example of Cr/Al Ratio in Coating Layer 20A

As illustrated in FIG. 5B, the Cr/Al ratio in the coating layer 20A may continuously change in the thickness-wise direction of the coating layer 20A. When the Cr/Al ratio in the target region of the coating layer 20A is not constant, the mean value of the Cr/Al ratios in such a region may be used as the Cr/Al ratio in the region.

In the example illustrated in FIG. 5B, the Cr/Al ratio in the coating layer 20A is substantially constant in the first coating layer 21. The Cr/Al ratio in the coating layer 20A is locally maximum in the second film 32 included in the second coating layer 22 and the fourth film 34 included in the third coating layer 23. The Cr/Al ratio in the coating layer 20A is locally minimum in the first film 31 included in the second coating layer 22 and the third film 33 included in the third coating layer 23.

Here, not only the Cr/Al ratio in the second film 32 may be larger than the Cr/Al ratio in the first coating layer 21, but also a local maximum value of the Cr/Al ratio in the second film 32 may be larger than the Cr/Al ratio in the first coating layer 21. Not only the Cr/Al ratio in the fourth film 34 may be larger than the Cr/Al ratio in the second film 32, but also the local maximum value of the Cr/Al ratio in the fourth film 34 may be larger than the local maximum value of the Cr/Al ratio in the second film 32.

Not only the Cr/Al ratio in the first film 31 may be smaller than the Cr/Al ratio in the first coating layer 21, but also the local minimum value of the Cr/Al ratio in the first film 31 may be smaller than the Cr/Al ratio in the first coating layer 21. Not only the Cr/Al ratio in the third film 33 may be smaller than the Cr/Al ratio in the first film 31, but also the local minimum value of the Cr/Al ratio in the third film 33 may be smaller than the local minimum value of the Cr/Al ratio in the first film 31.

Although the coating layer 20A in which the first coating layer 21, the first film 31, the second film 32, the third film 33, and the fourth film 34 are sequentially layered on the base 10 is provided, the first coating layer 21, the second film 32, the first film 31, the fourth film 34, and the third film 33 may be sequentially layered on the base 10.

### Examples of First Coating Layer 21, Second Coating Layer 22, and Third Coating Layer 23

As illustrated in FIG. 6A, the first coating layer 21 may include a region in which a plurality of compound layers 21a and a plurality of compound layers 21b are alternately layered. Here, a Ti/Al ratio and a Cr/Al ratio in the compound layer 21a are different from a Ti/Al ratio and a Cr/Al ratio in the compound layer 21b, respectively. For example, the Ti/Al ratio in the compound layer 21a is higher than the Ti/Al ratio in the compound layer 21b, and the Cr/Al ratio in the compound layer 21b is higher than the Cr/Al ratio in the compound layer 21a. A mean value of the thicknesses of the compound layer 21a and the compound layer 21b is 1 nm or more and 10 nm or less.

In such a case, the first coating layer 21 can have improved hardness. This can improve the strength of the first coating layer 21. As a result, the longevity of the coated tool 1 can be extended.

As illustrated in FIG. 6B, the first film 31 included in the second coating layer 22 may include a region in which a plurality of compound layers 31a and a plurality of compound layers 31b are alternately layered. Here, a Ti/Al ratio and a Cr/Al ratio in the compound layer 31a are different from a Ti/Al ratio and a Cr/Al ratio in the compound layer 31b, respectively. For example, the Ti/Al ratio in the compound layer 31a is higher than the Ti/Al ratio in the compound layer 31b, and the Cr/Al ratio in the compound layer 31b is higher than the Cr/Al ratio in the compound layer 31a. A mean value of the thicknesses of the compound layer 31a and the compound layer 31b is 1 nm or more and 10 nm or less.

In such a case, the hardness of the first film 31 and accordingly, the hardness of the second coating layer 22 can be improved. This can improve the strength of the first film 31, and accordingly, the strength of the second coating layer 22. As a result, the longevity of the coated tool 1 can be extended.

As illustrated in FIG. 6B, the second film 32 included in the second coating layer 22 may include a region in which a plurality of compound layers 32a and a plurality of compound layers 32b are alternately layered. Here, a Ti/Al ratio and a Cr/Al ratio in the compound layer 32a are different from a Ti/Al ratio and a Cr/Al ratio in the compound layer 32b, respectively. For example, the Cr/Al ratio in the compound layer 32a is higher than the Cr/Al ratio in the compound layer 32b, and the Ti/Al ratio in the compound layer 32b is higher than the Ti/Al ratio in the compound layer 32a. A mean value of the thicknesses of the compound layer 32a and the compound layer 32b is 1 nm or more and 10 nm or less.

In such a case, the hardness of the second film 32 and accordingly, the hardness of the second coating layer 22 can be improved. This can improve the strength of the second film 32, and accordingly, the strength of the second coating layer 22. As a result, the longevity of the coated tool 1 can be extended.

As illustrated in FIG. 6C, the third film 33 included in the third coating layer 23 may include a region in which a plurality of compound layers 33a and a plurality of compound layers 33b are alternately layered. Here, a Ti/Al ratio and a Cr/Al ratio in the compound layer 33a are different from a Ti/Al ratio and a Cr/Al ratio in the compound layer 33b, respectively. For example, the Ti/Al ratio in the compound layer 33a is higher than the Ti/Al ratio in the compound layer 33b, and the Cr/Al ratio in the compound layer 33b is higher than the Cr/Al ratio in the compound layer 33a. A mean value of the thicknesses of the compound layer 33a and the compound layer 33b is 1 nm or more and 10 nm or less.

In such a case, the hardness of the third film 33 and accordingly, the hardness of the third coating layer 23 can be improved. This can improve the strength of the third film 33, and accordingly, the strength of the third coating layer 23. As a result, the longevity of the coated tool 1 can be extended.

As illustrated in FIG. 6C, the fourth film 34 included in the third coating layer 23 may include a region in which a plurality of compound layers 34a and a plurality of compound layers 34b are alternately layered. Here, a Ti/Al ratio and a Cr/Al ratio in the compound layer 34a are different from a Ti/Al ratio and a Cr/Al ratio in the compound layer 34b, respectively. For example, the Cr/Al ratio in the compound layer 34a is higher than the Cr/Al ratio in the compound layer 34b, and the Ti/Al ratio in the compound layer 34b is higher than the Ti/Al ratio in the compound layer 34a. A mean value of the thicknesses of the compound layer 34a and the compound layer 34b is 1 nm or more and 10 nm or less.

In such a case, the fourth film 34 and accordingly, the third coating layer 23 can have improved hardness. This improves the strength of the fourth film 34 and the strength of the third coating layer 23. As a result, the longevity of the coated tool 1 can be extended.

The ratio of the elements in the coating layer or the film included in the coating layer 20A can be identified by, for example, analysis based on X-ray photoelectron spectroscopy (XPS) or analysis using an energy dispersive X-ray spectrometer (EDS) attached to a scanning transmission electron microscope (STEM). The presence of the plurality of compound layers alternately layered in the film included in the coating layer 20A can be confirmed by a bright-field image or a high-angle annular dark-field image obtained by a scanning transmission electron microscope (STEM), or analysis using an energy dispersive X-ray spectrometer (EDS).

### Intermediate Layer 11

As illustrated in FIG. 4, an intermediate layer 11 may be located between the base 10 and the coating layer 20A serving as the coating layer 20. Specifically, the intermediate layer 11 has one surface (here, a lower surface) in contact with the upper surface of the base 10 and another surface (here, an upper surface) in contact with the lower surface of the coating layer 20A (for example, the first coating layer 21).

The intermediate layer 11 has higher adhesion to the base 10 than the coating layer 20A. Examples of metal elements having such characteristics include Zr, Hf, V, Nb, Ta, Cr, Mo, W, Al, Si, Y, and Ti. The intermediate layer 11 contains at least one metal element among the above metal elements. For example, the intermediate layer 11 may contain Ti. Si is a metalloid element, but in the present specification, it is assumed that metalloid elements are also included in metal elements.

When the intermediate layer 11 contains Ti, a content percentage of Ti in the intermediate layer 11 may be 1.5 atomic % or more. For example, the content percentage of Ti in the intermediate layer 11 may be 2.0 atomic % or more.

The intermediate layer 11 may contain components other than the above-described metal elements (Zr, Hf, V, Nb, Ta, Cr, Mo, W, Al, Si, Y, and Ti). However, in terms of adhesion to the base 10, the intermediate layer 11 may contain at least 95 atomic % or more of the above metal elements in a combined amount. The intermediate layer 11 may contain 98 atomic % or more of the above metal elements in a combined amount. The ratio of the metal components in the intermediate layer 11 can be identified by, for example, analysis using an energy dispersive X-ray spectrometer (EDS) attached to a scanning transmission electron microscope (STEM).

Thus, when the intermediate layer 11 having higher wettability with the base 10 than the coating layer 20A is provided between the base 10 and the coating layer 20A, the adhesion between the base 10 and the coating layer 20A can be improved. Since the intermediate layer 11 also has high adhesion to the coating layer 20A, the coating layer 20A is less likely to separate from the intermediate layer 11.

The thickness of the intermediate layer 11 may be, for example, 0.1 nm or more and less than 20 nm.

### Coating Layer 20B According to Second Embodiment

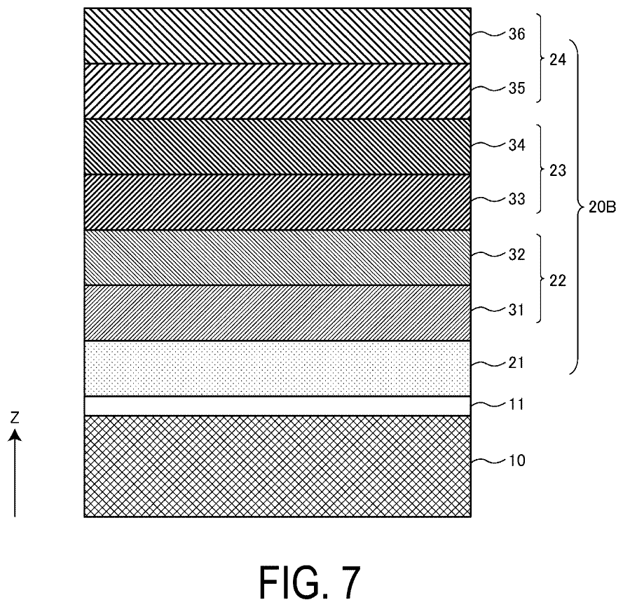

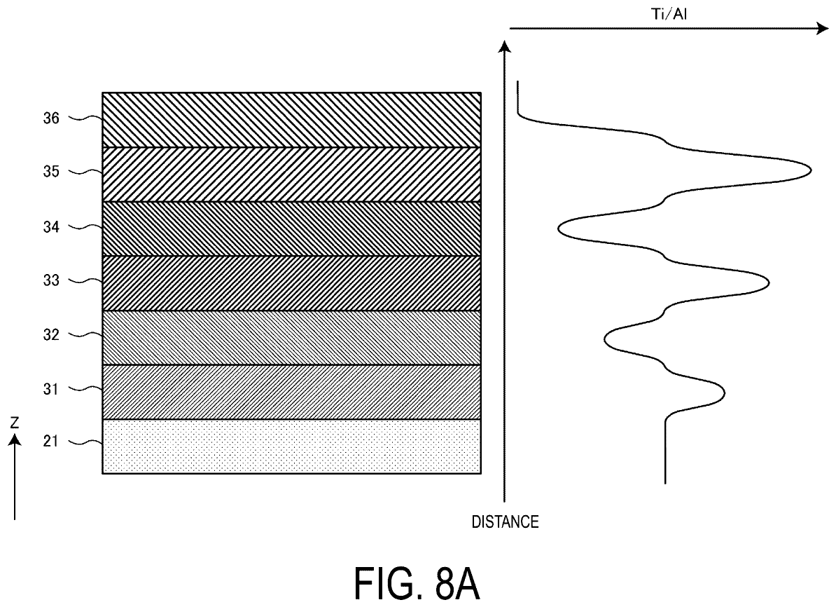

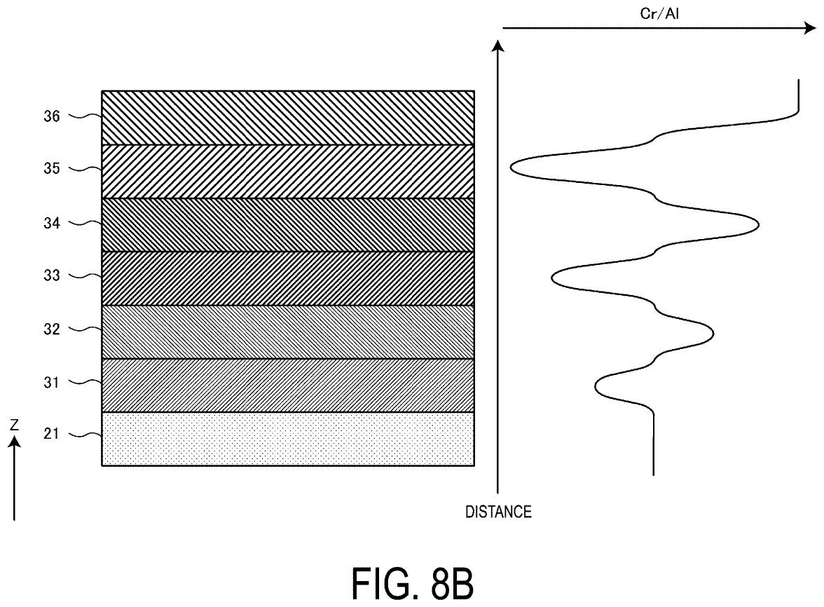

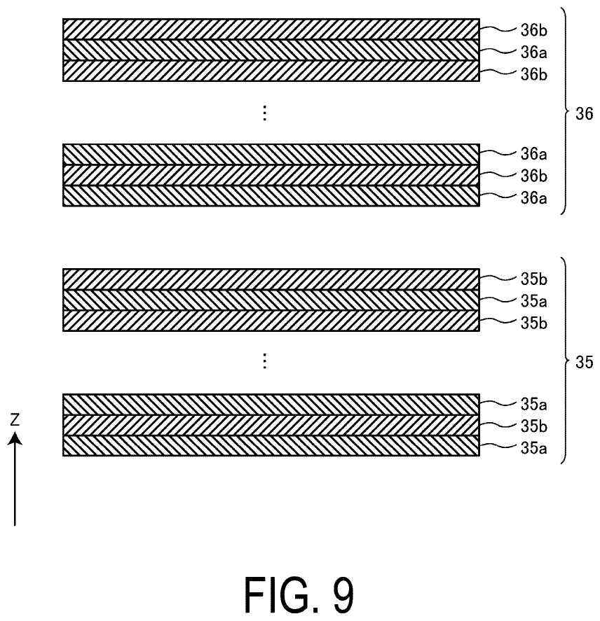

A specific configuration of the coating layer 20B according to a second embodiment will be described with reference to FIGS. 7, 8A, 8B, and 9. FIG. 7 is a cross-sectional view illustrating an example of a coating layer according to the second embodiment. FIG. 8A is a schematic view describing a Ti/Al ratio in the coating layer according to the second embodiment. FIG. 8B is a schematic view describing a Cr/Al ratio in the coating layer according to the second embodiment. FIG. 9 is a cross-sectional view illustrating an example of a fourth coating layer included in the coating layer according to the second embodiment.

As illustrated in FIG. 7, the coating layer 20B according to the second embodiment is different from the coating layer 20A according to the first embodiment in that the coating layer 20B according to the second embodiment further includes a fourth coating layer 24 located on the third coating layer 23. The coating layer 20B according to the second embodiment that is the same as, and/or similar to, the coating layer 20A according to the first embodiment in configuration will not be described.

### Fourth Coating Layer 24

As illustrated in FIG. 7, the fourth coating layer 24 includes a fifth film 35 and a sixth film 36.

The fifth film 35 contains Al, Ti, and N. The fifth film 35 may be an AlTiN film containing AlTiN, which is a nitride of Al and Ti, for example. Note that the expression “AlTiN” means that Al, Ti, and N are present at any ratio, and does not necessarily mean that Al, Ti, and N are present at a ratio of 1:1:1. The fifth film 35 may further contain Cr. In such a case, the fifth film 35 may be an AlTiCrN film containing AlTiCrN, which is a nitride of Al, Ti, and Cr, for example. The fifth film 35 has a thickness of, for example, 200 nm or more and 400 nm or less.

The sixth film 36 contains Al, Cr, and N. The sixth film 36 may be an AlCrN film containing AlCrN, which is a nitride of Al and Cr, for example. Note that the expression “AlCrN” means that Al, Cr, and N are present at any ratio, and does not necessarily mean that Al, Cr, and N are present at a ratio of 1:1:1. The sixth film 36 may further contain Ti. In such a case, the sixth film 36 may be an AlTiCrN film containing AlTiCrN, which is a nitride of Al, Ti, and Cr, for example. The sixth film 36 has a thickness of, for example, 200 nm or more and 400 nm or less.

The fifth film 35 has a Ti/Al ratio higher than a Ti/Al ratio in the third film 33. Here, the Ti/Al ratio means a ratio of the number of Ti atoms to the number of Al atoms. This can further improve the wear resistance and the chipping resistance of the coating layer 20B. The fifth film 35 may have a Cr/Al ratio lower than a Cr/Al ratio in the third film 33.

The sixth film 36 has a Cr/Al ratio higher than a Cr/Al ratio in the fourth film 34. Here, the Cr/Al ratio means a ratio of the number of Cr atoms to the number of Al atoms. This can further improve the lubricity and the anti-adhesion properties of the coating layer 20B. The sixth film 36 may have a Ti/Al ratio lower than a Ti/Al ratio in the fourth film 34.

The fourth coating layer 24 can further improve the wear resistance and the chipping resistance of the coating layer 20B and also further improve the lubricity and the anti-adhesion properties of the coating layer 20A. This further extends the longevity of the coated tool 1.

In the coating layer 20B, the third coating layer 23 acts so as not to significantly increase the residual stresses between the base 10 and the fourth coating layer 24 serving as a coating layer located on the third coating layer 23.

A Ti/Al ratio in the fifth film 35 may be 0.8 or more and 1.2 or less. When the Ti/Al ratio in the fifth film 35 is 0.8 or more, the coating layer 20B can have improved wear resistance and chipping resistance. When the Ti/Al ratio in the fifth film 35 is 1.2 or less, the residual stresses between the base 10 and the coating layer 20B is avoided from significantly increasing. This reduces separation or cracking between the base 10 and the coating layer 20B. This further extends the longevity of the coated tool 1.

The Cr/Al ratio in the sixth film 36 may be 0.8 or more and 1.2 or less. When the Cr/Al ratio in the sixth film 36 is 0.8 or more, the coating layer 20B can have improved lubricity and anti-adhesion properties. When the Cr/Al ratio in the sixth film 36 is 0.8 or more and 1.2 or less, the residual stresses between the base 10 and the coating layer 20B is avoided from significantly increasing. This reduces separation or cracking between the base 10 and the coating layer 20B. This further extends the longevity of the coated tool 1.

### Example of Ti/Al Ratio in Coating Layer 20B

As illustrated in FIG. 8A, the Ti/Al ratio in the coating layer 20B may continuously change in a thickness-wise direction of the coating layer 20B. When the Ti/Al ratio in the target region of the coating layer 20B is not constant, the mean value of the Ti/Al ratios in such a region may be used as the Ti/Al ratio in the region.

In the example illustrated in FIG. 8A, the Ti/Al ratio in the coating layer 20B is also locally maximum in the fifth film 35 included in the fourth coating layer 24. The Ti/Al ratio in the coating layer 20B is also locally minimum in the sixth film 36 included in the fourth coating layer 24.

Here, a local maximum value of the Ti/Al ratio in the fifth film 35 is larger than a local maximum value of the Ti/Al ratio in the third film 33. On the other hand, a local minimum value of the Ti/Al ratio in the sixth film 36 is smaller than a local minimum value of the Ti/Al ratio in the fourth film 34. The local minimum value of the Ti/Al ratio in the sixth film 36 is, for example, substantially 0.

### Example of Cr/Al Ratio in Coating Layer 20B

As illustrated in FIG. 8B, the Cr/Al ratio in the coating layer 20B may continuously change in a thickness-wise direction of the coating layer 20B. When the Cr/Al ratio in the target region of the coating layer 20B is not constant, a mean value of the Cr/Al ratios in such a region may be used as the Cr/Al ratio in the region.

In the example illustrated in FIG. 8B, the Cr/Al ratio in the coating layer 20B is also maximum in the sixth film 36 included in the fourth coating layer 24. The Cr/Al ratio in the coating layer 20B is also locally minimum in the fifth film 35 included in the fourth coating layer 24.

Here, a local maximum value of the Cr/Al ratio in the sixth film 36 is larger than a local maximum value of the Cr/Al ratio in the fourth film 34. On the other hand, a local minimum value of the Cr/Al ratio in the fifth film 35 is smaller than a local minimum value of the Cr/Al ratio in the third film 33. The local minimum value of the Cr/Al ratio in the fifth film 35 is, for example, substantially 0.

Although the coating layer 20B in which the first coating layer 21, the first film 31, the second film 32, the third film 33, the fourth film 34, the fifth film 35, and the sixth film 36 are sequentially layered on the base 10 is provided, the first coating layer 21, the second film 32, the first film 31, the fourth film 34, the third film 33, the sixth film 36, and the fifth film 35 may be sequentially layered on the base 10.

### Example of Fourth Coating Layer 24

As illustrated in FIG. 9, the fifth film 35 included in the fourth coating layer 24 may include a region in which a plurality of compound layers 35a and a plurality of compound layers 35b are alternately layered. Here, a Ti/Al ratio in the compound layers 35a is different from a Ti/Al ratio in the compound layers 35b. For example, the Ti/Al ratio in the compound layers 35a is higher than the Ti/Al ratio in the compound layers 35b. A mean value of the thicknesses of the compound layer 35a and the compound layer 35b is 1 nm or more and 10 nm or less.

In such a case, the fifth film 35 and accordingly, the fourth coating layer 24 can have improved hardness. In particular, the fourth coating layer 24 at a high temperature can have improved hardness. As a result, the fifth film 35, and accordingly, the fourth coating layer 24 can have improved strength. In particular, the fourth coating layer 24 can have improved wear resistance. This further extends the longevity of the coated tool 1.

As illustrated in FIG. 9, the sixth film 36 included in the fourth coating layer 24 may include a region in which a plurality of compound layers 36a and a plurality of compound layers 36b are alternately layered. Here, a Cr/Al ratio in the compound layers 36a is different from a Cr/Al ratio in the compound layers 36b. For example, the Cr/Al ratio in the compound layers 36a is higher than the Cr/Al ratio in the compound layers 36b. A mean value of the thicknesses of the compound layer 36a and the compound layer 36b is 1 nm or more and 10 nm or less.

In such a case, the sixth film 36 and accordingly, the fourth coating layer 24 can have improved hardness. In particular, the fourth coating layer 24 at a high temperature can have improved hardness. As a result, the sixth film 36, and accordingly, the fourth coating layer 24 can have improved strength. In particular, the fourth coating layer 24 can have improved wear resistance. This further extends the longevity of the coated tool 1.

### Method of Manufacturing Coated Tool

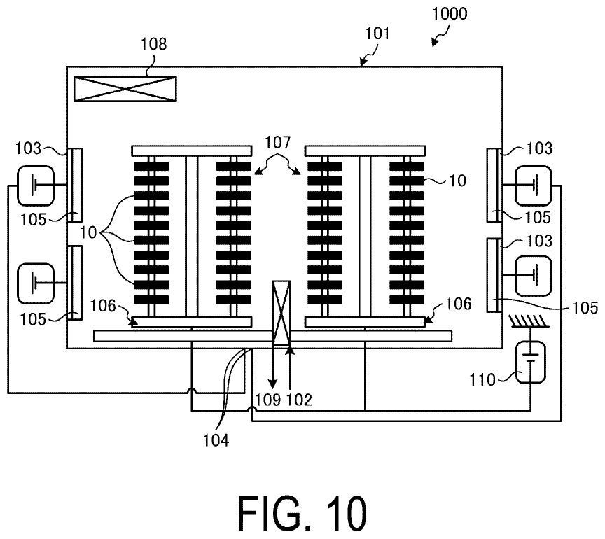

With reference to FIG. 10, an example of a method of manufacturing the coated tool 1 according to the embodiment will be described. FIG. 10 is a diagram schematically illustrating an example of a deposition apparatus for forming a coating layer on a base. The method of manufacturing the coated tool 1 is not limited to the method described below.

First, the base 10 having a shape of the coated tool 1 is manufactured using a well-known method. Subsequently, the coating layer 20 is formed on the surface of the base 10. For example, physical vapor deposition (PVD), such as ion plating or sputtering, can be used to deposit the coating layer 20. As an example, when forming the coating layer 20 by ion plating, for example, an arc ion plating deposition apparatus (hereinafter referred to as an AIP device) 1000 as illustrated in FIG. 10 can be used.

In the AIP device 1000 illustrated in FIG. 10, a gas such as N₂ or Ar is introduced into a vacuum chamber 101 from a gas inlet 102, and a high voltage is applied between a cathode electrode 103 and an anode electrode 104 located in the AIP device 1000 to generate gas plasma. Such plasma evaporates and ionizes a desired metal or ceramic from a target 105 to produce metal or ceramic ions in a high energy state. By adhering the ionized metal or ceramic to the surface of the base 10 as a sample, the surface of the base 10 is coated with the coating layer 20.

As illustrated in FIG. 10, a tower 107 on which multiple bases 10 are set may be placed on a sample support 106. A plurality of sample supports 106 (two sets in the figure) may be placed on a table (not illustrated). As illustrated in FIG. 10, a heater 108 for heating the bases 10, a gas outlet 109 for discharging gas out of the system, and a bias power supply 110 for applying a bias voltage to the bases 10 are provided.

Examples of the target 105 to be used may include a metal target independently containing metallic aluminum (Al), metallic titanium (Ti), metallic chromium (Cr), an alloy target obtained by combining these metals, and a mixture target including a powder or a sintered body of these nitrides. For example, as the target 105, a first alloy target obtained by combining Al and Ti and a second alloy target obtained by combining Al and Cr can be used.

A metal source is evaporated by arc discharge or glow discharge by using the target 105 to ionize the metal of the metal source and simultaneously react with nitrogen (N₂) gas of the nitrogen source to deposit the coating layer 20 on the surface of the base 10.

At this time, the sample support 106 is controlled so that a distance from a position of the target 105 to a position of the base 10 is 160 mm or more, for example, 260 mm or more. A large number of highly linear lines of magnetic force are generated from a central portion of a surface of the target 105 toward the base 10 so that a magnetic flux density in the vicinity of the base 10 is 0.2 to 0.8 millitesla (mT).

Nitrogen gas as a reactive gas may be introduced into the AIP device 1000 to create an atmospheric pressure of 2 to 10 Pa. The temperature of the base 10 is maintained at 300 to 500° C. Further, a bias voltage of from −50 to −200 V is applied to the base 10 to generate an arc discharge of from 30 to 200 A between the target 105 (cathode electrode 103) and the anode electrode 104. During such a time, metal is deposited on the base 10 while rotating and revolving the base 10.

Here, when each coating layer included in the coating layer 20 is layered on the base 10, a current value of the arc discharge generated between the target 105 serving as the cathode electrode 103 and the anode electrode 104 is controlled. For example, the current value of the arc discharge generated between the anode electrode 104 and the first alloy target obtained by combining Al and Ti, serving as the cathode electrode 103 or the second alloy target obtained by combining Al and Cr, serving as the cathode electrode 103 is controlled.

For example, in order to increase (decrease) the Ti/Al ratio in the coating layer or the film included in the coating layer 20, the current value of the arc discharge generated between the first alloy target obtained by combining Al and Ti, serving as the cathode electrode 103 and the anode electrode 104 is increased (or decreased).

For example, in order to increase (decrease) the Cr/Al ratio in the coating layer or the film included in the coating layer 20, the current value of the arc discharge generated between the second alloy target obtained by combining Al and Cr, serving as the cathode electrode 103 and the anode electrode 104 is increased (or decreased).

The magnetic flux density in the vicinity of the base 10 can be controlled by controlling the magnetic field, for example, by installing an electromagnetic coil or a permanent magnet, which is a magnetic field generation source, in the vicinity of the target 105, by placing a permanent magnet inside the AIP device 1000, for example, in the central portion thereof, or by adjusting the position of the target 105 adjacent to the base 10.

The magnetic force is calculated by measuring the magnetic flux density at the position of the base 10 with a magnetic flux density meter. The magnetic flux density is expressed in units of millitesla (mT). The distance from the position of the target 105 to the position of the base 10 represents a distance measured at a position where the base 10 is closest to the target 105 and a distance where the base 10 is farthest from the target 105.

In deposition, when a period in which the base 10 comes closest to and faces the target 105 at each position of the base 10 as illustrated in FIG. 10 is a speed of rotation of the sample, the period of the difference in the composition between the heavy metal and the light metal in the thickness direction of the coating layer 20 can be adjusted by adjusting the speed of rotation. To be specific, the speed of rotation of the base 10 and the sample support 106 may be adjusted so as to have a period of 2 to 20 revolutions per minute (rpm).

During deposition, each of the sample supports 106 on which the bases 10 are placed rotates while the tower 107 rotates, and the table may be rotated such that the plurality of sample supports 106 revolve. When such a revolution timing is adjusted, the thickness of each compound layer including the first coating layer 21, the second coating layer 22 (the first film 31 and the second film 32), the third coating layer 23 (the third film 33 and the fourth film 34), and the fourth coating layer 24 (the fifth film 35 and the sixth film 36) can be controlled.

By applying the pulsed bias voltage, the time during which or the distance for which metal ions fly from the target 105 to the bases 10 can be adjusted. Thus, a difference in composition between the heavy metal component and the light metal component can also be provided during deposition.

For example, when the base 10 is placed so as to be close to and face the target 105, the heavy metal components from the target 105 linearly fly to the base 10, and the heavy metals are deposited on the base 10 more than the light metals. On the other hand, when the base 10 is placed so as to be away from the target 105 and not to face the target 105, a deposition amount of the heavy metal components is expected to decrease because the light metal components wrap around and are deposited on the base 10. At this time, it is conceivable that increasing the distance from the position of the target 105 to the position of the base 10 and maintaining a certain degree of magnetic flux density in the vicinity of the base 10 promotes wraparound of the light metal components and a difference in composition between the heavy metal components and the light metal components increases.

### Cutting Tool

A configuration of a cutting tool including the coated tool 1 described above will be described with reference to FIG. 11. FIG. 11 is a front view illustrating an example of the cutting tool according to the embodiment.

As illustrated in FIG. 11, a cutting tool 100 according to the embodiment includes the coated tool 1 and the holder 70 for fixing the coated tool 1.

The holder 70 is a rod-shaped member extending from a first end (upper end in FIG. 11) toward a second end (lower end in FIG. 11). The holder 70 is made of, for example, steel or cast iron. In particular, steel with high toughness of these members may be used.

The holder 70 includes a pocket 73 at an end portion on the first end side. The pocket 73 is a portion at which the coated tool 1 is mounted. The pocket 73 has a seating surface intersecting the rotation direction of the workpiece and a restraint side surface inclined with respect to the seating surface. The seating surface is formed with a screw hole into which the screw 75 to be described below is screwed.

The coated tool 1 is located in the pocket 73 of the holder 70 and is mounted on the holder 70 by the screw 75. That is, the screw 75 is inserted into the through hole 5 of the coated tool 1, and the tip of the screw 75 is inserted into the screw hole formed in the seating surface of the pocket 73 such that the threaded portions are screwed together. Thus, the coated tool 1 is mounted on the holder 70 such that a cutting edge portion 3 protrudes outward from the holder 70.

In the embodiment, a cutting tool used for so-called turning processing is described as an example. Examples of the turning processing include boring, external turning, and groove-forming. The cutting tool is not limited to a cutting tool used for turning processing. For example, the coated tool 1 may be used as a cutting tool used for milling processing. Examples of the cutting tools to be used for milling processing include milling cutters such as a plain milling cutter, a face milling cutter, a side milling cutter, and a groove milling cutter, and end mills such as a single-flute end mill, a multi-flute end mill, a tapered end mill, and a ball end mill.

### Example(s)

Example of the present disclosure will be specifically described below. The present disclosure is not limited to the following Example.

A coated tool according to Example was produced by forming a coating layer on a base made of a WC-based cemented carbide alloy by using an AIP device as illustrated in

FIG. 10. As a target, a first alloy target obtained by combining Al and Ti and a second alloy target obtained by combining Al and Cr were used. Metal ions generated from the first alloy target or the second alloy target were reacted with nitrogen gas to deposit the coating layer on the base.

Here, when the base was rotated and revolved and the coating layer was layered on the base, a current value of an arc discharge generated between the first alloy target or the second alloy target serving as a cathode electrode and an anode electrode was controlled as follows.

First, the current value of the arc discharge generated between the first alloy target and the anode electrode was set to 190 to 210 A, and the current value of the arc discharge generated between the second alloy target and the anode electrode was set to 190 to 210 A so that the first coating layer was layered on the base.

Next, the current value of the arc discharge generated between the first alloy target and the anode electrode was set to 90 to 110 A, and the current value of the arc discharge generated between the second alloy target and the anode electrode was set to 40 to 60 A so that the first film included in the second coating layer was layered on the first coating layer.

Subsequently, the current value of the arc discharge generated between the first alloy target and the anode electrode was set to 40 to 60 A, and the current value of the arc discharge generated between the second alloy target and the anode electrode was set to 90 to 110 A so that the second film included in the second coating layer was layered on the first film.

Next, the current value of the arc discharge generated between the first alloy target and the anode electrode was set to 110 to 130 A, and the current value of the arc discharge generated between the second alloy target and the anode electrode was set to 20 to 40 A so that the third film included in the third coating layer was layered on the second film.

Subsequently, the current value of the arc discharge generated between the first alloy target and the anode electrode was set to 20 to 40 A, and the current value of the arc discharge generated between the second alloy target and the anode electrode was set to 110 to 130 A so that the fourth film included in the third coating layer was layered on the third film.

Next, the current value of the arc discharge generated between the first alloy target and the anode electrode was set to 140 to 160 A, and the current value of the arc discharge generated between the second alloy target and the anode electrode was set to 0 to 10 A so that the fifth film included in the fourth coating layer was layered on the fourth film.

Finally, the current value of the arc discharge generated between the first alloy target and the anode electrode was set to 0 to 10 A, and the current value of the arc discharge generated between the second alloy target and the anode electrode was set to 140 to 160 A so that the sixth film included in the third coating layer was layered on the fifth film.

The coated tool thus manufactured was analyzed for elements contained in the coating layer or the film deposited on the base by X-ray photoelectron spectroscopy (XPS).

It was confirmed that each of the first film and the second film included in the first coating layer and the second coating layer, and the third film and the fourth film included in the third coating layer contained Al, Ti, Cr, and N. It was confirmed that the fifth film included in the fourth coating layer contained Al, Ti, and N. It was confirmed that the sixth film included in the fourth coating layer contained Al, Cr, and N.

It was confirmed that the Ti/Al ratios in the first coating layer, the first film, the second film, the third film, the fourth film, the fifth film, and the sixth film continuously changed with respect to a distance from the surface of the substrate in a thickness direction of the coating layer or the film, that is, in the direction perpendicular to the surface of the substrate. It was confirmed that the Cr/Al ratios in the first coating layer, the first film, the second film, the third film, the fourth film, the fifth film, and the sixth film continuously changed with respect to a distance from the surface of the substrate in a thickness direction of the coating layer or the film, that is, in the direction perpendicular to the surface of the substrate.

It was confirmed that the Ti/Al ratio (local maximum value: 0.8) in the first film was higher than the Ti/Al ratio (0.6) in the first coating layer. It was confirmed that the Cr/Al ratio (local maximum value: 0.8) in the second film was higher than the Cr/Al ratio (0.6) in the first coating layer. It was confirmed that the Ti/Al ratio (local maximum value: 1) in the third film was higher than the Ti/Al ratio (local maximum value: 0.8) in the first film. It was confirmed that the Cr/Al ratio (local maximum value: 1) in the fourth film was higher than the Cr/Al ratio (local maximum value: 0.8) in the second film. It was confirmed that the Ti/Al ratio (local maximum value: 1.4) in the fifth film was higher than the Ti/Al ratio (local maximum value: 1) in the third film. It was confirmed that the Cr/Al ratio (local maximum value: 1.2) in the sixth film was higher than the Cr/Al ratio (local maximum value: 1) in the fourth film.

The fifth film and the sixth film were subjected to elemental analysis by an energy dispersive X-ray spectrometer (EDS). For the fifth film and the sixth film, bright field images and high-angle annular dark-field images were obtained by a scanning transmission electron microscope (STEM).

It was confirmed that the fifth film included a region in which a plurality of first compound layers and a plurality of second compound layers were alternately layered, and the sixth film included a region in which a plurality of third compound layers and a plurality of fourth compound layers were alternately layered. It was confirmed that the Ti/Al ratio in the first compound layer was different from the Ti/Al ratio in the second compound layer, and the Cr/Al ratio in the third compound layer was different from the Cr/Al ratio in the fourth compound layer.

The crystal grain map and the inverse pole figure orientation map for the coating layer (fourth coating layer) were obtained by the TEM electron-diffraction mapping method. By analyzing such maps, it was confirmed that the coating layer included a plurality of crystal grains, and the plurality of crystal grains included crystal grains having a region with a crystallographic orientation continuously varying inside the coating layer. It was confirmed that the plurality of crystal grains included a region having a continuously varying crystallographic orientation.

By analysis using the TEM electron-diffraction mapping method, an orientation difference of 5° or more was analyzed as a crystal grain boundary. A crystal grain map was created by division into a case where the Σ3CSL (coincidence grain boundary) was not a crystal grain boundary and a case where the Σ3CSL (coincidence grain boundary) was a crystal grain boundary. Next, the average grain sizes D1 and D2 on each crystal grain map were obtained by taking a weighted average based on the area ratios on the crystal grain maps, and it was confirmed that the value of D2/D1 was 0.55 to 0.95. As a result of outputting an average KAM (local orientation difference) value of each crystal grain by using the crystal grain map data and the crystallographic orientation analysis system, it was confirmed that the ratio of crystal grains having an average KAM value of 1 or more was 50% or more and 80% or less.

An adjacent pixel having an orientation difference of 5° or more with respect to the pixel at the measurement center was excluded from the calculation of the KAM value because it was beyond the crystal grain boundary from the single crystal where the pixel at the measurement center was located. The sample used for the analysis was obtained by slicing the coating layer in a direction substantially parallel to the surface of the base material using an FIB method (μ-sampling method). The analysis was performed using the following devices and conditions.

### TEM Electron-Diffraction Mapping Method

Transmission electron microscope: JEM-ARM200F manufactured by JEOL Ltd.
Crystallographic orientation analysis system: ASTAR manufactured by NanoMega
Measurement conditions acceleration voltage: 200 kV
Measurement area: 2 μm×2 μm
Measurement step: 10 nm

### Cutting Test

Cutting tests were performed on the coated tool according to Example and coated tools according to conventional products (a conventional product 1 and a conventional product 2) as comparative examples. The test conditions for the cutting tests were as follows. Cutting tests were conducted under the following conditions using a carbide grade for drilling (model number: 2ZDK060-HP-OH (internal coolant type) φ6 mm) as the base.
(1) Cutting method: drilling
(2) Workpiece: SUS304
(3) Cutting speed Vc: 80 m/min
(4) Feed amount per revolution f: 0.07 mm/rev
(5) Axial depth of cut H: 12 mm
(6) Machining mode: Wet
(7) Evaluation Method: Drilling was performed on the base under the above conditions, and a maximum wear amount (mm) of a cutting edge of the coated tool after 1232 holes were formed in the workpiece was measured. The maximum wear amount of the cutting edge was defined as a maximum value of the depth from the surface of a flank face of the cutting edge to a portion where the wear was observed.

Table 1 shows the maximum wear amounts of the cutting edges of the coated tools according to Example and the coated tools according to the conventional products (the conventional product 1 and the conventional product 2) with respect to the number of holes formed in the workpiece.

TABLE 1

| | | Ratio (%) of crystal | |
|---|---|---|---|
| | | grains having average | Maximum wear |
| | | KAM value of 1.0 | amount of cutting |
| | D2/D1 | or more | edge (mm) |
| Example 1 | 0.84 | 56 | 0.033 |
| Example 2 | 0.95 | 85 | 0.042 |
| Example 3 | 0.55 | 47 | 0.047 |
| Conventional | 0.99 | 80 | 0.066 |
| product 1 | | | |
| Conventional | 0.52 | 35 | 0.088 |
| product 2 | | | |

As shown in Table 1, the maximum wear amount of the cutting edge of the coated tool according to Example with respect to the number of holes formed in the workpiece is smaller than the maximum wear amounts of the cutting edges of the coated tools according to the conventional products (the conventional product 1 and the conventional product 2) with respect to the same number of holes formed in the workpiece. Therefore, when the coated tool according to Example is compared with the coated tools according to the conventional products (the conventional product 1 and the conventional product 2), it was confirmed that in the coated tool according to Example, the wear resistance of the coated tool was improved.

In the coated tool according to the conventional product 2, significant chipping occurred at the corner portion of the coated tool by the time when the number of holes was 1232. On the other hand, in the coated tool according to Example, no significant chipping occurred in the coated tool. Therefore, it was confirmed that the coated tool according to Example could maintain the chipping resistance of the coated tool.

As described above, a coated tool (as an example, the coated tool 1) according to the embodiment includes a base (as an example, the base 10), and a coating layer (as an example, the coating layer 20) located on the base. The coating layer includes a plurality of crystal grains (for example, the crystal grains 20a and 20b). The plurality of crystal grains include crystal grains (for example, the crystal grain 20a) having a plurality of regions (as an example, a plurality of regions 20a1, 20a2) having crystallographic orientations different from each other. The crystallographic orientations of the plurality of crystal grains in the coating layer are analyzed from a planar direction of the coating layer by using a TEM electron-diffraction mapping method. D1 is an average grain size of a crystal grain evaluated by taking a weighted average based on an area ratio from a first crystal grain map created by using, as a crystal grain boundary, a region obtained by excluding a Σ3CSL (coincidence grain boundary) from a region in which an orientation difference between adjacent measurement points is 5° or more. D2 is an average grain size of a crystal grain evaluated by taking a weighted average based on an area ratio from a second crystal grain map created by using, as a crystal grain boundary, a region in which an orientation difference between adjacent measurement points is 5° or more and the Σ3CSL (coincidence grain boundary). In this case, a value of D2/D1 is 0.55 to 0.95.

Therefore, the coated tool according to the embodiment can extend the tool life.

The shape of the coated tool 1 illustrated in FIG. 1 is merely an example and does not limit the shape of the coated tool according to the present disclosure. The coated tool according to the present disclosure may include a body having, for example, a rotation axis and a rod-like shape extending from a first end toward a second end, a cutting edge located at the first end of the body, and a groove extending in a spiral shape from the cutting edge toward the second end of the body.

### Supplementary Note

### Supplementary Note (1)

A coated tool including:
a base; and
a coating layer located on the base, wherein
the coating layer includes a plurality of crystal grains,
the plurality of crystal grains include a crystal grain including a plurality of regions having crystallographic orientations different from each other, and
a value of D2/D1 is 0.55 to 0.95, where
the crystallographic orientations of the plurality of crystal grains in the coating layer are analyzed from a planar direction of the coating layer by using a TEM electron-diffraction mapping method,
D1 is an average grain size of a crystal grain evaluated by taking a weighted average based on an area ratio from a first crystal grain map created by using, as a crystal grain boundary, a region obtained by excluding a Σ3CSL (coincidence grain boundary) from a region in which an orientation difference between adjacent measurement points is 5° or more, and
D2 is an average grain size of a crystal grain evaluated by taking a weighted average based on an area ratio from a second crystal grain map created by using, as a crystal grain boundary, a region in which an orientation difference between the adjacent measurement points is 5° or more and the Σ3CSL (coincidence grain boundary).

### Supplementary Note (2)

The coated tool according to Supplementary Note (1), wherein
if the crystallographic orientations of the plurality of crystal grains in the coating layer are analyzed from a planar direction of the coating layer by using a TEM electron-diffraction mapping method, and a region in which an orientation difference between the adjacent measurement points is 5° or more and the Σ3CSL (coincidence grain boundary) are used as a crystal grain boundary,
when an average of KAM values is obtained for each crystal grain in a local orientation difference map (KAM map) measured by a crystallographic orientation analyzer,
a ratio of crystal grains having the average of KAM values of 1 or more is 50% or more and 80% or less.

### Supplementary Note (3)

The coated tool according to Supplementary Note (1) or (2), wherein the plurality of crystal grains include a composite nitride.

### Supplementary Note (4)

The coated tool according to any one of Supplementary Notes (1) to (3), wherein the plurality of crystal grains include:
a plurality of first crystal grains including a plurality of regions having crystallographic orientations different from each other; and
a plurality of second crystal grains having a constant crystallographic orientation, and the plurality of first crystal grains are located apart from each other.

### Supplementary Note (5)

The coated tool according to Supplementary Note (4), wherein the plurality of second crystal grains are located between the plurality of first crystal grains.

### Supplementary Note (6)

The coated tool according to Supplementary Note (4) or (5), wherein at least two of the plurality of second crystal grains are adjacent to each other.

### Supplementary Note (7)

A cutting tool including:
a holder having a rod-like shape, the holder including a pocket at an end portion of the holder; and
the coated tool according to any one of Supplementary Notes (1) to (6), the coated tool being located in the pocket.

Further effects and/or variations can be easily derived by those skilled in the art. Thus, a wide variety of aspects of the present invention are not limited to the specific details and representative embodiments represented and described above. Accordingly, various changes are possible without departing from the spirit or scope of the general inventive concepts defined by the appended claims and their equivalents.

### REFERENCE SIGN(S)

1 Coated tool
2 Tip body
3 Cutting edge portion
5 Through hole
10 Base
11 Intermediate layer
20, 20A, 20B Coating layer
20a, 20b Crystal grain
20a1, 20a2 Region
21 First coating layer
22 Second coating layer
23 Third coating layer
24 Fourth coating layer
31 First film
32 Second film
33 Third film
34 Fourth film
35 Fifth film
36 Sixth film
21a, 21b, 31a, 31b, 32a, 32b, 33a, 33b, 34a, 34b, 35a, 35b, 36a, 36b Compound layer
70 Holder
73 Pocket
75 Screw
100 Cutting tool
101 Vacuum chamber
102 Gas inlet
103 Cathode electrode
104 Anode electrode
105 Target
106 Sample support
107 Tower
108 Heater
109 Gas outlet
110 Bias power supply
1000 AIP device

1. A coated tool comprising:
a base; and
a coating layer located on the base, wherein
the coating layer comprises a plurality of crystal grains,
the plurality of crystal grains comprise a crystal grain comprising a plurality of regions having crystallographic orientations different from each other, and
a value of D2/D1 is 0.55 to 0.95, where
the crystallographic orientations of the plurality of crystal grains in the coating layer are analyzed from a planar direction of the coating layer by using a TEM electron-diffraction mapping method,
D1 is an average grain size of a crystal grain evaluated by taking a weighted average based on an area ratio from a first crystal grain map created by using, as a crystal grain boundary, a region obtained by excluding a Σ3CSL (coincidence grain boundary) from a region in which an orientation difference between adjacent measurement points is 5° or more, and
D2 is an average grain size of a crystal grain evaluated by taking a weighted average based on an area ratio from a second crystal grain map created by using, as a crystal grain boundary, a region in which an orientation difference between the adjacent measurement points is 5° or more and the Σ3CSL.

2. The coated tool according to claim 1, wherein
a ratio of crystal grains having an average of KAM values of 1 or more is 50% or more and 80% or less, where
the crystallographic orientations of the plurality of crystal grains in the coating layer are analyzed from a planar direction of the coating layer by using a TEM electron-diffraction mapping method,
a region in which an orientation difference between the adjacent measurement points is 5° or more and the Σ3CSL are used as a crystal grain boundary, and
the average of KAM values is obtained for each crystal grain in a local orientation difference map (KAM map) measured by a crystallographic orientation analyzer.

3. The coated tool according to claim 1, wherein the plurality of crystal grains comprise a composite nitride.

4. The coated tool according to claim 1, wherein
the plurality of crystal grains comprise:
a plurality of first crystal grains, each of the first crystal grains comprising a plurality of regions having crystallographic orientations different from each other; and
a plurality of second crystal grains, each of the second crystal grains having a constant crystallographic orientation, and
the plurality of first crystal grains are located apart from each other.

5. The coated tool according to claim 4, wherein the plurality of second crystal grains are located between the plurality of first crystal grains.

6. The coated tool according to claim 4, wherein at least two of the plurality of second crystal grains are adjacent to each other.

7. A cutting tool comprising:
a holder having a rod-like shape, the holder comprising a pocket at an end portion of the holder; and
the coated tool according to claim 1 located in the pocket.
